(19) United States
(12) Patent Application Publication
(10) Pub. No.: US 2026/0019067 A1
(43) Pub. Date: Jan. 15, 2026

(54) SYSTEMS AND METHODS FOR SCALED PHASE BRIDGING PULSE WIDTH MODULATION (SPB-PWM)

(71) Applicant: Analog Devices International Unlimited Company, Limerick (IE)

(72) Inventors: Emre KIRKAYA, Dublin (IE); Viren Bhosale, Dublin (IE); Suresh Hariharn, San Jose, CA (US); Mark Derhake, Chandler, AZ (US)

(21) Appl. No.: 19/270,265

(22) Filed: Jul. 15, 2025

Related U.S. Application Data
(60) Provisional application No. 63/671,650, filed on Jul. 15, 2024.

(51) Int. Cl. H03K 3/017

(52) U.S. Cl. CPC H03K 3/017

(57) ABSTRACT

In an aspect, a method and system are provided. In an aspect, the method includes generating, by a pulse width modulation (PWM) signal generator, a PWM signal. The method further includes detecting, by the PWM signal generator, a phase change of the PWM signal from a lower value to a higher value or from the higher value to the lower value. The method also includes compensating, by the PWM signal generator, for a temporary decrease to a duty cycle of the PWM signal caused by the phase change by inserting one or more pulses into a period of time of the PWM signal occupied by the phase difference caused by a phase change of the PWM signal.

### CROSS REFERENCE

The present application claims priority to U.S. Provisional Patent Application No. 63/671,650, filed on Jul. 15, 2024, the entire contents of which are incorporated herein by reference.

### TECHNICAL FIELD

Aspects of the present disclosure relate generally to pulse width modulation and, more particularly, to systems and methods for scaled phase bridging pulse width modulation (SPB-PWM).

### BACKGROUND

In light emitting diode (LED) dimming matrix applications (with the term “matrix” referring to any configuration of more than one LED or LED string), the LEDs can be dimmed in a staggered fashion in order to reduce peak currents through the current source output capacitor reducing noise, electromagnetic interference (EMI), and stress on the output capacitor, and thus improving overall performance. This action is called phase shifting and is common in any application requiring multiple LEDs. Typically, the phase of each LED is set or programmed before the LEDs are turned on. This is done to prevent the problem of LEDs flickering due to real time updates done when the LEDs are dimming. However, the use of pulse width modulation in LED matrix dimming applications is not without deficiency and suffers from flicker during phase shift operations. While prevalent and readily visible in LED dimming matrix applications as flicker, this phenomena exists in any type of application that uses PWM.

### SUMMARY

The following presents a simplified summary of one or more aspects to provide a basic understanding of such aspects. This summary is not an extensive overview of all contemplated aspects and is intended to neither identify key or critical elements of all aspects nor delineate the scope of any or all aspects. Its sole purpose is to present some concepts of one or more aspects in a simplified form as a prelude to the more detailed description that is presented later.

According to an aspect, a method for pulse width modulation (PWM) is provided. The method includes generating, by a PWM signal generator, a PWM signal. The method further includes detecting, by the PWM signal generator, a phase change of the PWM signal from a lower value to a higher value or from the higher value to the lower value. The method also includes compensating, by the PWM signal generator, for a temporary decrease to a duty cycle of the PWM signal caused by the phase change by inserting one or more pulses into a period of time of the PWM signal occupied by a phase difference caused by the phase change of the PWM signal.

According to yet another aspect, a system for pulse width modulation (PWM) is provided. The system includes a PWM signal generator configured to generate a PWM signal.

The PWM signal generator is further configured to detect a phase change of the PWM signal from a lower value to a higher value or from the higher value to the lower value. The PWM signal generator is also configured to compensate for a temporary decrease to a duty cycle of the PWM signal caused by the phase change by inserting one or more pulses into a period of time of the PWM signal occupied by a phase difference caused by the phase change of the PWM signal.

To the accomplishment of the foregoing and related ends, the one or more aspects comprise the features hereinafter fully described and particularly pointed out in the claims.

The following description and the annexed drawings set forth in detail certain illustrative features of the one or more aspects. These features are indicative, however, of but a few of the various ways in which the principles of various aspects may be employed, and this description is intended to include all such aspects and their equivalents.

### BRIEF DESCRIPTION OF THE DRAWINGS

The disclosed aspects will hereinafter be described in conjunction with the appended drawings, provided to illustrate and not to limit the disclosed aspects, wherein like designations denote like elements, and in which.

FIG. 1 is a diagram showing an example PWM signal over time, in accordance with an example aspect.

FIG. 2 is a block diagram showing an example PWM system, in accordance with an example aspect.

FIG. 3 is a block diagram further showing the PWM signal generator of FIG. 2, in accordance with an example aspect.

FIG. 4 is a signal diagram showing a total LED voltage corresponding to a first LED voltage and a second LED voltage that are dimmed with a 0-degree phase shift is shown, in accordance with an example aspect.

FIG. 5 is a signal diagram showing a total LED voltage corresponding to a first LED voltage and a second LED voltage that are dimmed with a 180-degree phase shift, in accordance with an example aspect.

FIG. 6 is a timing diagram showing an example first flicker scenario, in accordance with an example aspect.

FIG. 7 is a timing diagram showing an example second flicker scenario, in accordance with an example aspect.

FIG. 8 is a timing diagram showing an example third flicker scenario, in accordance with an example aspect.

FIG. 9 is a timing diagram showing different sized gaps for different phase changes to which aspects of the present disclosure can be applied, in accordance with an example aspect.

FIG. 10 is an example first flicker elimination solution, in accordance with an example aspect.

FIG. 11 is an example second flicker elimination solution, in accordance with an example aspect.

FIGS. 12-17 are flow diagrams showing an example method for scaled phase bridging pulse width modulation (SPB-PWM), in accordance with example aspect.

### DETAILED DESCRIPTION

Aspects of the present disclosure are directed to scaled phase bridging pulse width modulation (SPB-PWM). Aspects of the present disclosure increase a duty cycle of a PWM signal during a phase change of the PWM signal during which the duty cycle of the PWM signal is expected to drop using a method described as the SPB-PWM method. By using the SPB-PWM method, aspects of the present disclosure enable maintaining a consistent average voltage/power to a load device during phase changes to a PWM signal. Hence, consistence and expected performance of the load device can be assured due to the consistent average voltage/power being applied to the load device.

To increase the duty cycle during a phase change of a PWM signal from a lower value to a higher value or from the higher value to the lower value, one or more pulses may be injected or inserted into a period of time of the PWM signal occupied by a phase difference caused by a phase change of the PWM signal. Injection of the one or more pulses increases the on-time of the PWM signal, thus increasing the duty-cycle of the PWM signal. In this way, gaps in voltage signals which prevent undesirable effects in connected load devices can be avoided.

Aspects of the present disclosure apply to scenarios in which the phase change of a PWM signal is from a higher value to a lower value and to scenarios in which the phase change of a PWM signal is from a lower value to a higher value. In scenarios in which a phase change of a PWM signal is from a higher value to a lower value, an insertion of the one or more pulses injected into the period of time of the PWM signal occupied by the phase change difference caused by the phase change may be delayed. In an aspect, the insertion of the one or more pulses may be delayed in order to prevent two or more pulses from overlapping during a given time period. In an aspect relating to a phase change from a higher value to a lower value, a full period of the PWM signal is used for scaling the one or more pulses. In an aspect relating to a phase change from a lower value to a higher value, a gap period of the PWM signal is used for scaling the one or more pulses.

As used herein, “‘scaling’ the one or more pulses injected into a period of time of the PWM signal occupied by a phase difference caused by a phase change of the PWM signal” refers to matching the duty cycle of each of the one or more pulses to the expected and/or set duty cycle of the PWM cycle, and fitting the one or more pulses within a resultant gap caused by the phase change in the voltage level of the PWM signal in the case of a phase change from a lower value to a higher value or fitting the one or more pulses within an entire period of a phase change from a higher value to a lower value.

Pulse Width Modulation (PWM) is a technique used to control the average power delivered to an electrical load (load device) by varying the width of a series of pulses in a periodic waveform. By adjusting the “on” time of the pulse relative to the “off” time, the average voltage or power delivered to a device can be effectively controlled. PWM allows for precise control of various electronic components, including motors, lighting such as light emitting diodes (LEDs), audio amplification, telecommunications, power supplies, heating elements, buzzers, sensors, robotics, computer motherboards, solar panels, and other electronic components.

PWM can be used for motor control, such as but not limited to use in DC motors, servo motors, brushless motors, and so forth. Regarding DC motors, PWM can be used to control the speed of DC motors, allowing for smooth and efficient speed adjustments to the DC motors.

Regarding servo motors, PWM can be used to control the precise position of servo motors, commonly found in robotics, radio-controlled models, and automation systems. Regarding brushless motors, PWM can be used to control the speed and direction of brushless motors, offering more efficient and precise control.

PWM can be used for light control, such as but not limited to use in LEDs, incandescent lighting, and so forth. Regarding LEDs, PWM can be used to dim LEDs, allowing for smooth brightness adjustments, and creating visual effects like fading. Regarding incandescent lighting, PWM can also be used to dim traditional incandescent bulbs. By adjusting the pulse width, you can control the brightness of a bulb. A higher pulse width (longer “on” time) will make the bulb appear brighter, while a shorter pulse width (shorter “on” time) will make the bulb appear dimmer.

PWM can be used for power supplies, such as but not limited to use in switch-mode power supplies (SMPS), buck and boost converters, battery charging, and so forth. Regarding SMPS, PWM can often be a fundamental component in SMPS, enabling efficient voltage regulation and power conversion. Regarding buck and boost converters, PWM can be used in buck and boost converters to adjust input voltages to stable output voltages, making the buck and boost converters crucial for battery-powered devices. PWM can be used to control the charging process, ensuring efficient and safe charging of batteries.

PWM can be used for audio amplification, such as but not limited to use in class D audio amplifiers, and so forth. Regarding class D audio amplifiers, PWM can be used to generate analog audio signals, allowing for compact and efficient audio amplification.

PWM can be used for telecommunication, such as but not limited to use for data encoding, remote controls, and so forth. Regarding data encoding, PWM can be used to encode information for transmission over data lines. Regarding remote controls, PWM signals can be used to transmit control signals in remote controls for various devices.

PWM can be used for other application including, but not limited to, heating elements, buzzers, sensors, robotics, computer motherboards, solar panels, and so forth. Regarding heating elements, PWM can be used to regulate the temperature of heating elements. Regarding buzzers, PWM can be used to control the loudness of buzzers. Regarding sensors, some sensors can use PWM for signal transmission or to modulate their output. Regarding robotics, PWM can be used to control various robotic components, such as motors and actuators. Regarding computer motherboards, PWM can be used to regulate the heat output of the board. Regarding solar panels, PWM can be used to control the output of solar panels, maximizing their energy capture.

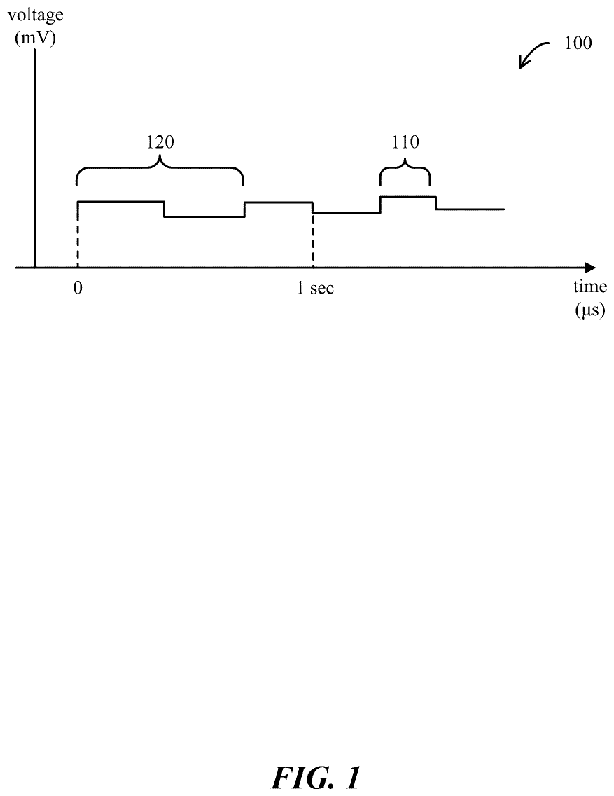

Referring to FIG. 1, an example PWM signal 100 is shown, in accordance with an example aspect. The PWM signal 100 includes a series of square wave pulses, where the voltage is switched between two levels (e.g., high and low, or 5V and 0V).

The PWM signal 100 has the following characteristics.

Pulse Width (PW) 110: The “pulse width” refers to the duration of the “on” time of the pulse. PWM uses a varying pulse width. The “on” time of the pulse is varied, or modulated, based on the desired average voltage/power.

Duty Cycle: The duty cycle is the ratio of the pulse width to the total period of the waveform. In an aspect, the duty cycle can be expressed as a percentage.

Frequency 120: The rate at which the pulses repeat is referred to as the “frequency.” PWM uses a fixed-frequency carrier wave (the square wave). Frequency is measured in Hertz, or cycle per second. The period T of a

$$signal = \frac{1}{frequency} .$$

Average Voltage/Power: By changing the duty cycle, the average voltage or power delivered to the load can be controlled. A higher duty cycle (longer “on” time) results in a higher average voltage/power. A lower duty cycle (shorter “on” time) results in a lower average voltage/power.

Aspects of the present disclosure can maintain the average volage of a PWM signal to be stable by inserting one or more scaled PWM pulses to maintain an intended duty cycle specified for a given application. Applications can include, but are not limited to, motor control, lighting control, audio amplification, telecommunications, power supplies, heating elements, buzzers, sensors, robotics, computer motherboards, solar panels, and so forth.

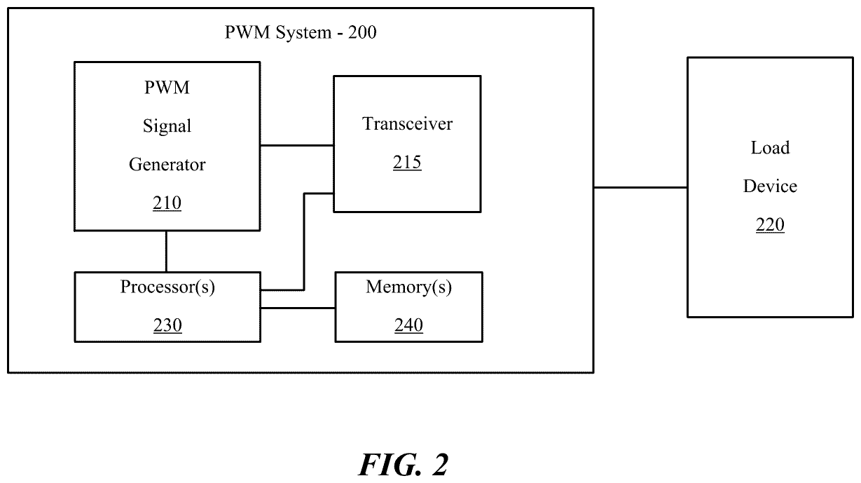

Referring to FIG. 2, an example PWM system 200 is shown, in accordance with an example aspect.

The PWM system 200 includes a PWM signal generator 210, a PWM transceiver 215, and a PWM load device 220.

The PWM signal generator 210 generates a PWM signal by varying the width of a pulse over a fixed period. The PWM signal generator 210 can include using comparator-based methods with sawtooth or triangle waves, microcontroller-based methods, specialized PWM ICs, digital logic gates, digital-to-analog converters (DACs), software-based PWM signal generation (e.g., Python®), and so forth.

Regarding comparator-based methods, a triangle or sawtooth wave (carrier signal) is compared with a control voltage (modulation signal) using a comparator. The output of the comparator is a PWM signal, where the pulse width is determined by the intersection of the two signals. The duty cycle, which is the ratio of the on-time to the total period, is controlled by the modulation signal's amplitude.

Regarding microcontroller-based method, microcontrollers often have built-in timer/counter modules that can generate PWM signals. These built-in timer/counter modules typically involve setting a counter, a compare value (CMP), and a digital output pin. The counter increments or decrements, and when it matches the CMP value, the output toggles, creating a PWM waveform. The duty cycle is controlled by adjusting the CMP value.

Regarding specialized PWM ICs, dedicated PWM ICs, like the 555 timer, can be used to generate PWM signals. These dedicated PWM ICs often involve configuring resistors and capacitors to set the frequency and duty cycle. For example, a 555 timer can be configured to produce a PWM signal by controlling the charging and discharging times of a capacitor.

Regarding digital logic gates, PWM signals can be generated using combinations of logic gates, such as an exclusive-OR (XOR) gate.

Regarding DACs, some DACs can produce PWM outputs by using a sawtooth or triangle wave (as the carrier wave) and comparing the sawtooth or triangle wave with an analog input (as the modulating input).

Regarding software-based PWM signal generation, software can simulate PWM by toggling a digital output pin on and off with specific delays to create the desired pulse width.

PWM transceiver 215 is configured to receive and transmit PWM signals.

PWM load device 220 can be any of: a motor; a light; an audio amplifier; a telecommunications device, a power supply, a heating element, a buzzer, a sensor, a robotic, a computer motherboard, a solar panel, and so forth. In an aspect, the PWM load device 220 is local to the PWM signal generator 210. In another aspect, the PWM load device 220 is remote from the PWM signal generator 210.

In an aspect, the PWM signal generator 210 and the transceiver 215 includes one or more processors 230 operatively coupled to the PWM signal generator 210 and the transceiver, and one or more memories 240 operatively coupled to the one or more processors 230 for storing program code for scaled phase bridging pulse width modulation (SPB-PWM).

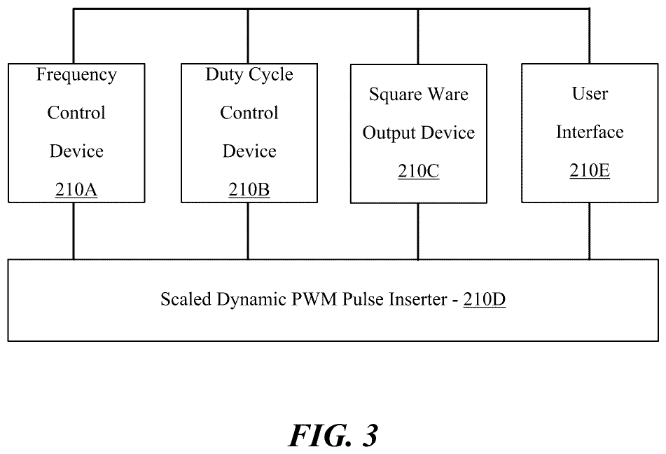

Referring to FIG. 3, the PWM signal generator 210 of FIG. 2 is further shown, in accordance with an example aspect.

In an aspect, the PWM signal generator 210 includes a frequency control device 210A for controlling a frequency of an output PWM signal, a duty cycle control device 210B for controlling the duty cycle of the output PWM signal, a square wave output device 210C for generating the output PWM signal, a scaled phase bridging pulse width modulation (SPB-PWM) pulse inserter 210D for generating and inserting one or more duty cycle correction pulses to a PWM signal subject to phase change, and a user interface 210E and receiving inputs and/or displaying outputs directed to frequency adjustment, duty cycle control, current frequency, current duty cycle, average voltage, and so forth. In an aspect, the one or more duty cycle correction pulses are used to lengthen a duty cycle that has been undesirably shortened due to a phase change from a lower value to a higher value or from the higher value to the lower value.

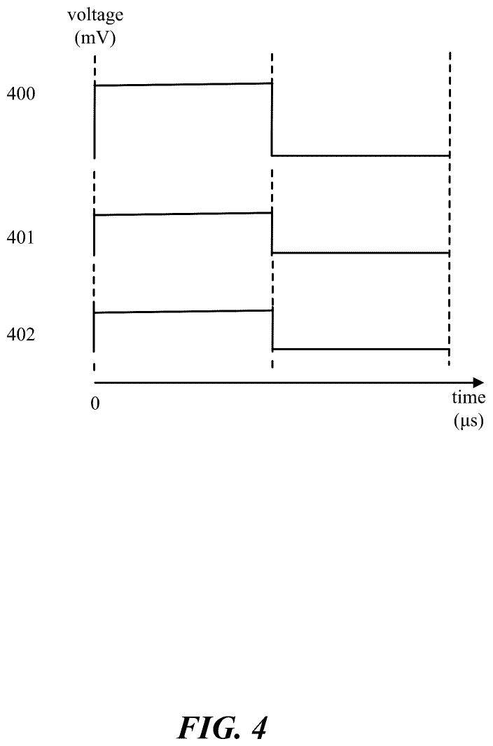

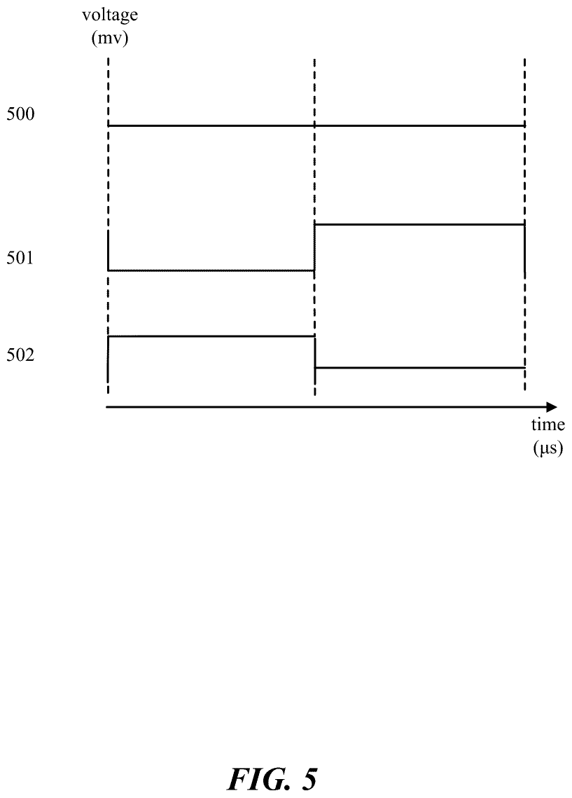

Referring to FIGS. 4-5, signal diagrams showing two example light emitting diodes (LEDs) with phase shift scenarios to which the present aspects can be applied, in accordance with an illustrative aspects of the present disclosure.

Referring to FIG. 4, a total LED voltage 400 corresponding to a first LED voltage 401 of a first LED (not shown) and a second LED voltage 402 of a second LED (not shown) that are dimmed with a 0-degree phase shift is shown, in accordance with an example aspect. The total LED voltage 400 is equal to the sum of first LED voltage 401 and second LED voltage 402. In the example of FIG. 4, the frequency of the first LED voltage 401 and the frequency of the second LED voltage is 150 Hz, the duty cycle of the first LED voltage 401 and the second LED voltage is 50 percent, and the pulse height of each pulse in each of the first LED voltage 401 and the second LED voltage 402 is 1X volts, where X is an integer or a fraction.

The total LED voltage is thus equal to 2X volts for a 0-degree phase shift. The preceding frequency value (150 Hz), duty cycle value (50%), and magnitudes (multiples of X) relate to example values to which aspects of the present disclosure can be applied. Other frequency values, duty cycles, and magnitudes can also be used, depending upon the application and the involved load device(s).

Referring to FIG. 5, a total LED voltage 500 corresponding to a first LED voltage 501 of a first LED (now shown) and a second LED voltage 502 of a second LED (not shown) that are dimmed with a 180-degree phase shift is shown, in accordance with an example aspect. The total LED voltage 500 is equal to the sum of first LED voltage 501 and second LED voltage 502. In the example of FIG. 5, the frequency of the first LED voltage 401 and the frequency of the second LED voltage is 150 Hz, the duty cycle of the first LED voltage 401 and the second LED voltage is 50 percent, and the pulse height of each pulse in each of the first LED voltage 401 and the second LED voltage 402 is 1X volts, where X is an integer or a fraction.

The total LED voltage is thus equal to 0X volts for a 180-degree phase shift. The preceding frequency value (150 Hz), duty cycle value (50%), and magnitudes (multiples of X) relate to example values to which aspects of the present disclosure can be applied. Other frequency values, duty cycles, and magnitudes can also be used, depending upon the application and the involved load device(s).

As used herein, the term “LED flickering” is defined as any noticeable brief change in the brightness of the light output of an LED due to changing the phase of the LED while the LED is actively dimming. This flickering effect can be caused by either increasing or decreasing the phase of the LED while the LED is dimming. Existing technologies typically implement either direct phase updates or delayed phase updates when changing the phase of the addressed LED.

It is to be appreciated that while the following scenarios are describing with respect to flicking during LED dimming, aspects of the present disclosure can be applied to any device that uses PWM signals as such device will suffer a similar detrimental operation during the phase change where there is a gap in the average voltage/power. Aspects of the present disclosure provide one or more “corrective” pulses that increase the duty cycle of the PWM signal during a period of time of the PWM signal occupied by a phase difference caused by the phase change of the PWM signal. In this way, an undesirable and unintended drop in the duty cycle of the PWM signal can be compensated to provide consistent average voltage/power to the device for proper operation of the device.

### First Flicker Scenario—Effect of Increasing LED Phase During LED Dimming

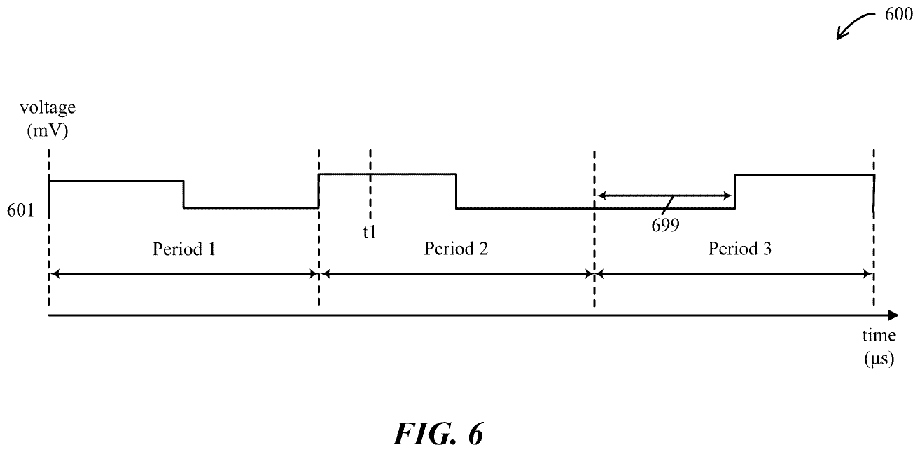

Referring to FIG. 6, a timing diagram showing an example first flicker scenario 600 is shown, in accordance with an example aspect.

The first flicker scenario 600 is an example of a conventional direct phase update that is performed when changing the phase of an addressed LED from a lower value to a higher value.

In the first flicker scenario, flicker occurs when increasing the LED phase from a lower value to a higher value. In the first flicker scenario 600, the phase of the first LED 601 is programmed to be updated from 0 degrees to 180 degrees at time t1 during LED dimming period 2. This phase change is updated at the start of period 3. As shown, due to the phase update, there is now a period of time 699 where the LED is off for longer than usual. That is, period of time 699 is caused by the phase change from 0 degree to 180 degrees during period 3 and results in a longer “off-time” of the first LED 601. In the case of PWM-based lighting, this increased off-time relative to the static PWM duty cycle can cause visible changes in the light output the instance that the increased off-time happens.

### Second Flicker Scenario—Effect of Decreasing LED Phase During LED Dimming

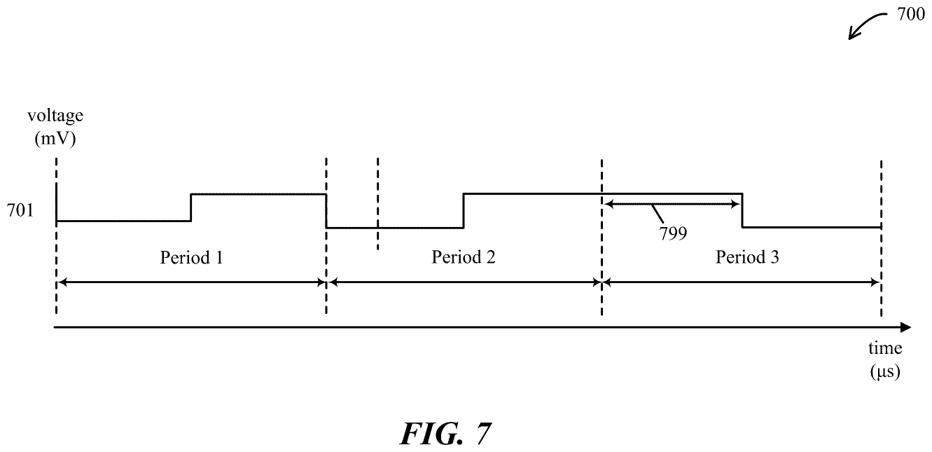

Referring to FIG. 7, a timing diagram showing an example second flicker scenario 700 is shown, in accordance with an example aspect.

The second flicker scenario 700 is an example of a conventional direct phase update that is performed when changing the phase of an addressed LED from a higher value to a lower value.

In the second flicker scenario, flicker occurs when decreasing the LED phase of the first LED 701 from a higher value to a lower value. In flicker scenario 1, the change in brightness was caused due to the LED off-time increasing. When decreasing phase from a higher value to a lower value, the opposite can occur. Now the LED can be on for a longer period of time 799 relative to the LED's static PWM duty cycle. That is, period of time 799 is caused by the phase change from 180 degrees to 0 degrees during period 3, and results in an extended “on-time” of the first LED 701. This is an example of direct phase updating where individual LED pulses are allowed to overlap when changing from a higher phase to a lower one.

Third Flicker Scenario—Delayed Update Phase Shifting to Avoid Overlapping LED Dimming Pulses

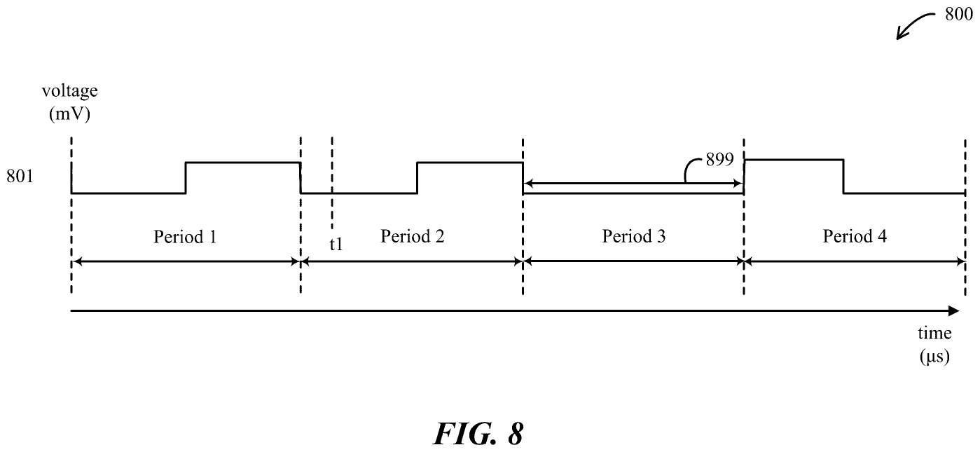

Referring to FIG. 8, a timing diagram showing an example third flicker scenario 800 is shown, in accordance with an example aspect.

The third flicker scenario 800 is an example of a conventional delayed phase update that is performed when changing the phase of an addressed LED from a higher value to a lower value.

In third flicker scenario 800, similar to first flicker scenario 600 and second flicker scenario 700, the phase of an LED 801 is programmed to be updated at time t1 during LED dimming period 2.

In the third flicker scenario 800, flicker occurs due to delayed update phase shifting to avoid overlapping LED dimming pulses. As shown with respect to FIG. 6 and FIG. 7, respectively, LED flickering can be caused by both increasing and decreasing the phase of the first LED 601 and 701, respectively.

Another phase update scheme is delayed phase updating as shown in FIG. 8. This type of phase update involves waiting one extra period before updating the new phase value to avoid LED pulses from overlapping. This version of phase updating can also cause flickering since when going from a higher phase to a lower phase (especially if the change is small) of a LED 801, there will now be one full period 899 (period 3) plus or minus the new phase update (now occurring in period 4). For example, when changing from 180 degrees to 0 degrees, the LED off-time caused by the phase shift will be one full period 899 (represented by period 3) assuming a 50% duty cycle.

A problem with existing real time phase shifting methods can cause changes in the LED brightness due to LED pulses either becoming too far apart, or too close together. There is no exact range of increasing or decreasing pulses that will cause all observers to notice flicker. For example, very small changes may not be visible. All existing methods can cause flicker with large enough changes in phase.

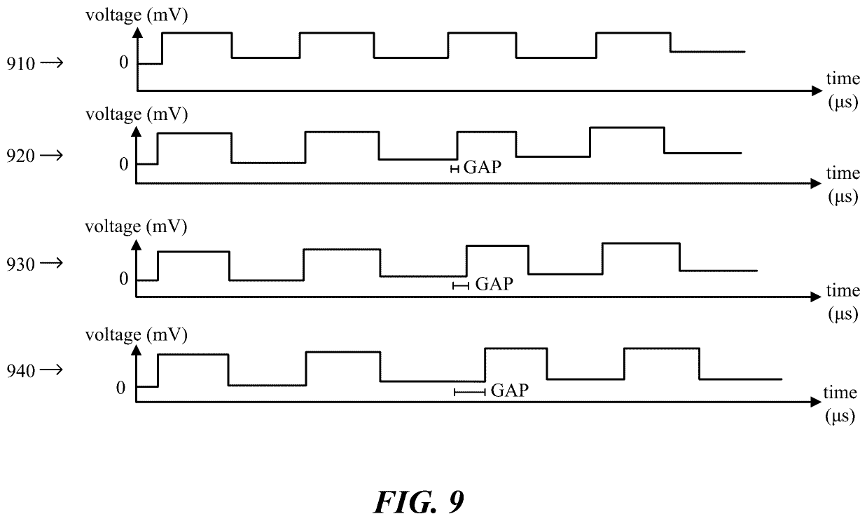

Referring to FIG. 9, a timing diagram showing different sized gaps to which aspects of the present disclosure can be applied is shown, in accordance with an example aspect.

PWM signal 910 has a 150 Hz frequency, a 50% duty cycle, and a 0-degree phase change.

PWM signal 920 has a 150 Hz frequency, a 50% duty cycle, and a 0-degree to 10-degree phase change. There is a small gap in the PWM signal 920 caused by the phase change from 0-degrees to 10-degrees.

PWM signal 930 has a 150 Hz frequency, a 50% duty cycle, and a 0-degree to 60-degree phase change. There is a larger gap in the PWM signal 930 caused by the phase change from 0-degrees to 60-degrees, as compared to the small gap in the PWM signal 920.

PWM signal 940 has a 150 Hz frequency, a 50% duty cycle, and a 0-degree to 90-degree phase change. There is the largest gap in the PWM signal 940 caused by the phase change from 0-degrees to 90-degrees, as compared to the small gap in the PWM signal 920 and the larger gap in the PWM signal 930.

Thus, as the phase change difference becomes greater, the gap in the duty cycle of the corresponding PWM signal becomes greater, causing negative effects such as lack of a full range of expected motion in a motor, flickering in a lighting system, less than an intended power level from a power amplifier or power supply, and so forth, depending upon the application of the PWM signal.

Thus, methods are provided for PWM signal phase shift change that eliminate any resultant flicker caused by a phase shift. Moreover, such methods eliminate any undesirable effects to the average voltage of a PWM signal during a phase shift in any application involving PWM signals including, but not limited to a motor, a light, an audio amplifier, a telecommunications device, a power supply, a heating element, a buzzer, a sensor, a robotic, a computer motherboard, a solar panel, and so forth.

To help alleviate the noticeable flicker effect due to phase changes on dimming LEDs as well as other applications that suffer similar effects during a phase change from a lower value to a higher value or from the higher value to the lower value, a method called scaled phase bridging pulse width modulation (SPB-PWM) is provided. The SPB-PWM method involves inserting an extra pulse (or pulses) depending on the length of the change of the phase shift update and the duty cycle of the LED that is being updated.

SPB-PWM can be performed by inserting one or more pulses into a period of time of a PWM signal occupied by a phase difference caused by a phase change of the PWM signal. In the case of inserting two or more pulses, the two or more pulses can have uniform widths or non-uniform widths. Equations are provided below for the following cases:
(I) a single pulse insertion case;
(II) a single pulse insertion case with approximation;
(III) N number of equal pulses insertion case; and
(IV) N number of non-equal pulses insertion case.

### (I) Single Pulse Insertion Case

$$- Assume , Period = 360 degrees$$

$$- if New Phase > Present Phase ; Phase Difference = New Phase - Present Phase$$

$$- Else , Phase Difference = 360 - Present Phase + New Phase$$

$$- New Period = Phase Difference$$

$$- \frac{New Period}{Period} = \frac{Phase Difference}{360}$$

$$- New Period = \frac{Phase Difference}{360} \times Period$$

$$- Scaling Factor = \frac{Phase Difference}{360}$$

$$- New Pulse Width = Scaling Factor \times Pulse Width$$

$$- Duty Cycle = \frac{Pulse Width}{Period} = \frac{New Pulse Width}{New Period}$$

(II) Single Pulse Insertion Case with Approximation

The same equations apply here as described above for (I) Single Pulse Insertion Case, with the following exceptions:

$$- New Period = \frac{Phase Difference}{360} \times Period$$

$$- Scaling Factor = \frac{Phase Difference}{360}$$

$$- New Pulse Width = Scaling Factor \times Pulse Width \pm β$$

$$- Duty Cycle = \frac{Pulse Width}{Period} ≅ \frac{New Pulse Width \pm β}{New Period}$$

β is small enough to keep the duty cycle approximately the same

### (III) N Number of Equal Pulses Insertion Case

The same equations apply here as described above for (I) Single Pulse Insertion Case, with the following exceptions:

$$- New Period = New Period 1 + New Period 2 + ⋯ + New Period N$$

$$- \frac{New Period}{N} = New Period 1 = New Period 2 = ⋯ = New Period N$$

$$- New Pulse Width = New Pulse Width 1 + New Pulse Width 2 + ⋯ + New Pulse Width N$$

$$- \frac{New Pulse Width}{N} = New Pulse Width 1 = New Pulse Width 2 = ⋯ =$$

### New Pulse Width N

$$Duty Cycle = \frac{New Pulse Width 1}{New Period 1} = \frac{New Pulse Width 2}{New Period 2} = ⋯ = \frac{New Pulse Width N}{New Period N}$$

### (IV) N Number of Non-Equal Pulses Insertion Case:

$$New Period ≅ New Period 1 + New Period 2 + ⋯ + New Period N$$

The new periods do not have to be equal

$$New Pulse Width ≅ New Pulse Width 1 + New Pulse Width 2 + ⋯ + New Pulse Width N$$

The new pulse widths do not have to be equal
Maintaining approximately the same duty cycle with the original PWM cycle is enough to keep the overall duty cycle the same.

$$Duty Cycle ≅ \frac{New Pulse Width 1}{New Period 1} ≅ \frac{New Pulse Width 2}{New Period 2} ≅ ⋯ ≅ \frac{New Pulse Width N}{New Period N}$$

### Examples for the Equations of Single Pulse Insertion Case:

### Example 1

$$PWM Frequency = 1 KHz$$

$$Thus , Period = 1 mS = 1000 uS$$

$$Duty Cycle = 50 \%$$

$$Pulse Width = 50 \% \times 1000 uS = 500 uS$$

$$Initial Phase ( Present Phase ) = 0 degrees$$

$$Target Phase ( New Phase ) = 90 degrees$$

$$New Phase > Present Phase then :$$

$$Phase Difference = 90 - 0 = 90 degrees$$

$$Scaling Factor = \frac{90}{360} = \frac{1}{4}$$

$$New Period = \frac{1}{4} \times 1000 = 250 uS$$

$$New Pulse Width = \frac{1}{4} \times 500 = 125 uS$$

$$New Duty Cycle = \frac{125 uS}{250 uS} = 50 \%$$

$$As a result New Duty Cycle =$$

$$Duty Cycle , then duty cycle has been maintained .$$

### Example 2

$$PWM Frequency = 500 Hz$$

$$Thus , Period = 2 mS = 2000 uS$$

$$Duty Cycle = 50 \%$$

$$Pulse Width = 50 \% \times 2000 uS = 1000 uS$$

$$Initial Phase ( Present Phase ) = 90 degrees$$

$$Target Phase ( New Phase ) = 0 degrees$$

New Phase<Present Phase then:

$$Phase Difference = 360 - 90 + 0 = 270 degrees$$

$$Scaling Factor = \frac{270}{360} = \frac{3}{4}$$

$$New Period = \frac{3}{4} \times 2000 = 1500 uS$$

$$New Pulse Width = \frac{3}{4} \times 1000 = 750 uS$$

$$New Duty Cycle = \frac{750 uS}{1500 uS} = 50 \%$$

$$As a result New Duty Cycle =$$

$$Duty Cycle , then duty cycle has been maintained .$$

Examples for the Equations of Single Pulse Insertion Case with Approximation

### Example 1

$$PWM Frequency = 1 KHz$$

$$Thus , Period = 1 mS = 1000 uS$$

$$Duty Cycle = 50 \%$$

$$Pulse Width = 50 \% \times 1000 uS = 500 uS$$

$$Initial Phase ( Present Phase ) = 0 degrees$$

$$Target Phase ( New Phase ) = 90 degrees$$

New Phase>Present Phase then:

$$Phase Difference = 90 - 0 = 90 degrees$$

$$Scaling Factor = \frac{90}{360} = \frac{1}{4}$$

$$New Period = \frac{1}{4} \times 1000 = 250 uS$$

$$New Pulse Width = \frac{1}{4} \times 500 = 125 + 0.5 uS$$

$$New Duty Cycle = \frac{125.5 uS}{250 uS} = 50.2 \%$$

$$As a result New Duty Cycle ≅$$

$$Duty Cycle , then duty cycle has been maintained approximately .$$

### Example for the Equations of Multiple Equal Pulses Insertion Case

$$PWM Frequency = 1 KHz$$

$$Thus , Period = 1 mS = 1000 uS$$

$$Duty Cycle = 50 \%$$

$$Pulse Width = 50 \% \times 1000 uS = 500 uS$$

$$Initial Phase ( Present Phase ) = 0 degrees$$

$$Target Phase ( New Phase ) = 90 degrees$$

New Phase>Present Phase then:

$$Phase Difference = 90 - 0 = 90 degrees$$

$$Scaling Factor = \frac{90}{360} = \frac{1}{4}$$

$$N = 5 , thus 5 equal pulses will be inserted$$

$$New Period = \frac{1}{4} \times 1000 = 250 uS$$

$$\frac{New Period}{N} = \frac{250}{5} = New Period 1 = New Period 2 = New Period 3 = New Period 4 = New Period 5 = 50 uS$$

$$New Pulse Width = \frac{1}{4} \times 500 = 125 uS$$

$$\frac{New Pulse Width}{N} = \frac{125}{5} = New Pulse Width 1 = New Pulse Width 2 = New Pulse Width 3 = New Pulse Width 4 = New Pulse Width 5 = 25 uS$$

$$New Duty Cycle = \frac{125 uS}{250 uS} = 50 \%$$

$$New Duty Cycle = \frac{New Pulse Width 1}{New Period 1} = \frac{New Pulse Width 2}{New Period 2} = \frac{New Pulse Width 3}{New Period 3} = \frac{New Pulse Width 4}{New Period 4} = \frac{New Pulse Width 5}{New Period 5} = \frac{25 uS}{50 uS} = 50 \%$$

As a result New Duty Cycle=Duty Cycle, then duty cycle has been maintained.

### Examples for the Equations of Multiple Non-Equal Pulses Insertion Case

### Example 1

$$PWM Frequency = 500 Hz$$

$$Thus , Period = 2 mS = 2000 uS$$

$$Duty Cycle = 50 \%$$

$$Pulse Width = 50 \% \times 2000 uS = 1000 uS$$

$$Initial Phase ( Present Phase ) = 0 degrees$$

$$Target Phase ( New Phase ) = 90 degrees$$

New Phase>Present Phase then:

$$Phase Difference = 90 - 0 = 90 degrees$$

$$Scaling Factor = \frac{90}{360} = \frac{1}{4}$$

$$N = 2 , thus 2 non - equal pulses will be inserted$$

$$New Period = \frac{1}{4} \times 2000 = 500 uS$$

$$New Period 1 = 249 uS$$

$$New Period 2 = 251 uS$$

$$New Period ≅ New Period 1 + New Period 2$$

$$New Pulse Width 1 = 126 uS$$

$$New Pulse Width 2 = 124 uS$$

$$New Pulse Width = \frac{1}{4} \times 1000 = 250 uS$$

$$New Pulse Width ≅ New Pulse Width 1 + New Pulse Width 2$$

$$New Duty Cycle = \frac{250 uS}{500 uS} ≅ 50 \%$$

$$As a result New Duty Cycle =$$

$$Duty Cycle , then duty cycle has been maintained approximately .$$

### Example 2

$$PWM Frequency = 500 Hz$$

$$Thus , Period = 2 mS = 2000 uS$$

$$Duty Cycle = 50 \%$$

$$Pulse Width = 50 \% \times 2000 uS = 1000 uS$$

$$Initial Phase ( Present Phase ) = 0 degrees$$

$$Target Phase ( New Phase ) = 90 degrees$$

New Phase>Present Phase then:

$$Phase Difference = 90 - 0 = 90 degrees$$

$$Scaling Factor = \frac{90}{360} = \frac{1}{4}$$

$$N = 2 , thus 2 non - equal pulses will be inserted$$

$$New Period = \frac{1}{4} \times 2000 = 500 uS$$

$$New Period 1 = 248 uS$$

$$New Period 2 = 252 uS$$

$$New Period = New Period 1 + New Period 2$$

$$New Pulse Width 1 = 124 uS$$

$$New Pulse Width 2 = 126 uS$$

$$New Pulse Width = \frac{1}{4} \times 1000 = 250 uS$$

$$New Pulse Width = New Pulse Width 1 + New Pulse Width 2$$

$$New Duty Cycle = \frac{124 uS}{248 uS} = \frac{126 uS}{252 uS} = 50 \%$$

As a result New Duty Cycle=Duty Cycle, then the duty cycle has been maintained.
   Scenario 1—Increasing Phase from a Lower Value to a Higher Value

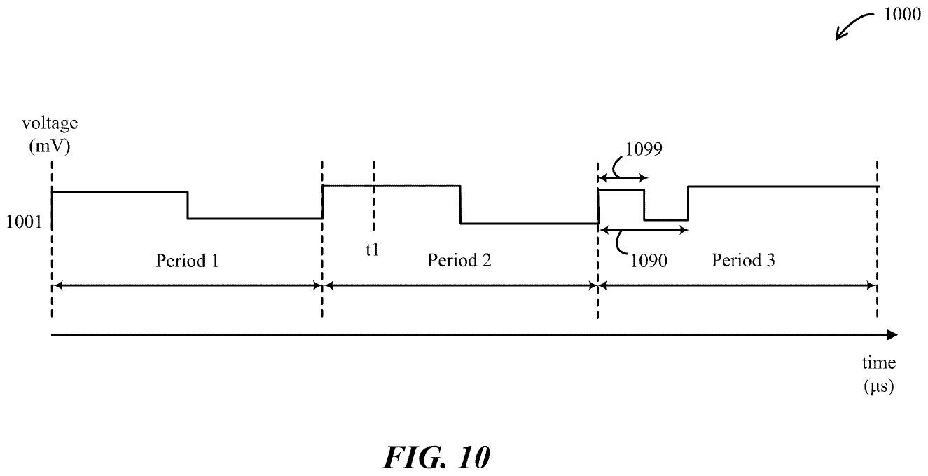

Referring to FIG. 10, a diagram of an example first scaled phase bridging pulse width modulation (SPB-PWM) solution 1000 is shown, in accordance with an example aspect.

The first SPB-PWM solution 1000 is used for the scenario when the phase of an LED voltage 1001 is increased from a lower value to a higher value. When increasing the phase of the LED voltage 1001 voltage from a lower value to a higher value, the SPB-PWM solution 1000 will insert one or more pulses into the period 1090 occupied by the phase difference caused by the phase update. Regarding LED lighting, this insertion of the one or more pulses will help mitigate any visible LED flicker since the LED is now on for a longer period. Other applications such as motor control will also benefit in receiving a constant average voltage/power for accurate motor control, e.g., without unintended stoppages or slowdowns.

In the first SPB-PWM solution 1000, flicker occurs when increasing the phase of the LED voltage 1001 from a lower value to a higher value. In the first SW-PWM solution 1000, the phase of the LED voltage 1001 is updated from 0 degrees to 180 degrees at time t1 during LED dimming period 2. This phase change is updated at the start of period 3. As shown, due to the phase update, there is now a period 1090 where the LED voltage 1001 is off for longer than usual. This increased off-time of the LED voltage 1001 relative to the static PWM duty cycle is mitigated by the insertion of one or more pulses of a certain width 1099 during the off-time of the PWM duty cycle, creating a new period 1090 for the one or more pulses at the start of and within period 3.

Scenario 2—Decreasing Phase from a Higher Value to a Lower Value

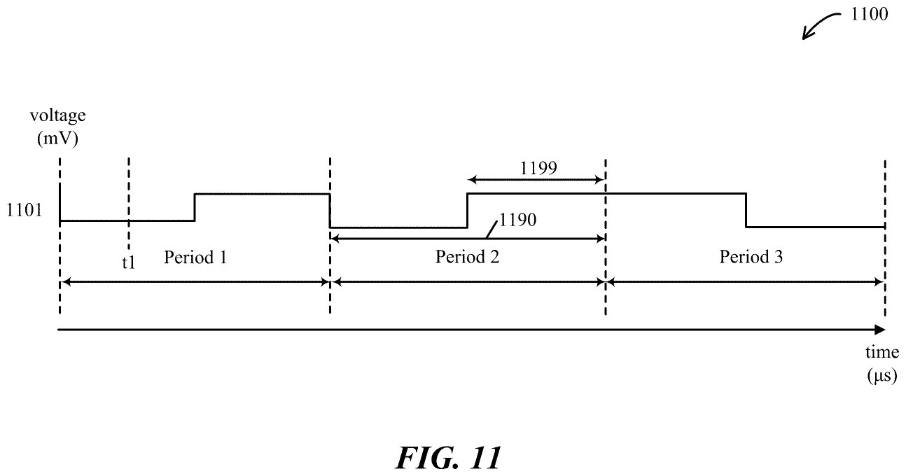

Referring to FIG. 11, a diagram of an example second SPB-PWM solution 1100 is shown, in accordance with an example aspect.

The second SPB-PWM solution 1100 used for the scenario when the phase of a LED voltage 1101 is decreased from a higher value to a lower value. When decreasing the phase of the LED voltage 1101 from the higher value to the lower value, the SPB-PWM solution 1100 uses delayed phase shift updating. Delayed updates are used to prevent LED pulses from overlapping. In this case, when the phase is changed from a higher value to a lower value, the new pulse added will follow the same calculation described before. The difference being that the new pulse 1199 is calculated using the full period for scaling. For example, if updating the phase from 180 to 0 degrees, the new pulse will still be the same size. That is, period 2 will include a new period 1190, equal to the duration of period 2, for the one or more pulses. This makes the phase update similar to the direct phase update method, but since the new period 1190 is defined using the above equations, the pulses will no longer overlap. Note there is no overlap now between pulses.

In the second SPB-PWM solution 1100, the phase of the LED voltage 1101 is updated from 180 degrees to 0 degrees at time t1 during LED dimming period 2. This phase change is updated at the start of period 3. As shown, due to the phase update, there is now a period where the LED is off for longer than usual. This increased off-time relative to the static PWM duty cycle is mitigated by the insertion of one or more pulses during the off-time of the PWM duty cycle.

SPB-PWM as described herein can be used to create one or more scaled pulses to help eliminate LED flicker when performing phase updates on LEDs that are actively dimming. These pulses, their timing, pulse width, scaled period, position in time, and number can be varied to further achieve flicker elimination and this document only describes one possible implementation. SPB-PWM will eliminate visible flicker in most scenarios, but since viewers may be more sensitive to changes in light, there may still be applications where flicker can be seen. As such, the described method mitigates the effect of flicker in a light or light matrix. Moreover, aspects of the present disclosure can be applied to any of a motor, an audio amplifier, a telecommunications device, a power supply, a heating element, a buzzer, a sensor, a robotic, a computer motherboard, a solar panel, and so forth. In these other devices, similar undesirable effects to the average output voltage/power provided to these other devices can be avoided. In particular, the gap in the PWM voltage signal, caused by the phase change from a lower value to a higher value or from the higher value to the lower value, and occurring in the period of time of the PWM signal occupied by a phase difference caused by the phase change of the PWM signal, can be compensated for by increasing the duty cycle in the period of time when the duty cycle undesirably decreases, that is, in the period of time of the PWM signal occupied by the phase difference caused by the phase change of the PWM signal.

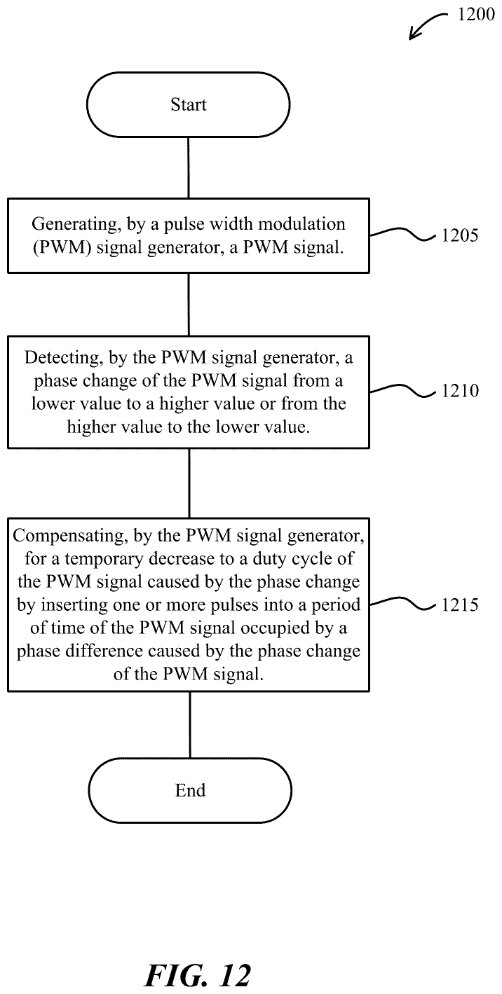

Referring now to FIGS. 12-16, one example of a method 1200 for scaled phase bridging pulse width modulation (SPB-PWM) is shown, in accordance with an example aspect. In an aspect, method 1200 compensates for undesirable duty-cycle changes in a PWM signal caused by a phase change to the PWM signal. Method 1200 may be performed by PWM signal generator of FIG. 2 and FIG. 3. Optional elements of PWM system 200 corresponding to optional features of PWM system 200 include transceiver 215 of FIG. 2. Boxes shown in dashes or dashes and dots are optional features.

Referring now to FIGS. 1-2 and FIGS. 12-16, at block 1205, the method 1200 includes generating, by a pulse width modulation (PWM) signal generator 210, a PWM signal. In an aspect, block 1205 may include receiving one or more user inputs, via user interface 210E of PWM signal generator 210 directed to setting a frequency of the PWM signal using the frequency control device 210A and setting a duty cycle of the PWM signal using the duty cycle control device 210B. The outputs of the frequency control device 210A and the duty cycle control device 210B may be provided to the square wave output device 210C to generate a PCM square wave with a certain frequency and a certain duty cycle.

At block 1210, the method 1200 includes detecting, by the PWM signal generator 210, a phase change of the PWM signal from a lower value to a higher value or from the higher value to the lower value.

At block 1215, the method 1200 includes compensating, by the PWM signal generator 210, for a temporary decrease to a duty cycle of the PWM signal caused by the phase change by inserting one or more pulses into a period of time of the PWM signal occupied by a phase difference caused by the phase change of the PWM signal. In an aspect, an insertion of the one or more pulses into the PWM signal is performed by the PWM signal generator 210 to cause a temporary increase to the duty cycle of the PWM signal that maintains at least one of an average voltage or an average power to a load device configured to receive the PWM signal. In an aspect, the SPB-PWM pulse inserter 210D of the PWM signal generator 210 inserts the one or more pulses into the PWM signal output from the square wave output device as adjusted by the frequency control device 210A with respect to frequency and as adjusted by the duty cycle control device 210B with respect to duty cycle. In this way, one or more pulses, also referred to as SPB-PWM pulses, may be inserted into the output square wave from the square wave output device 210C.

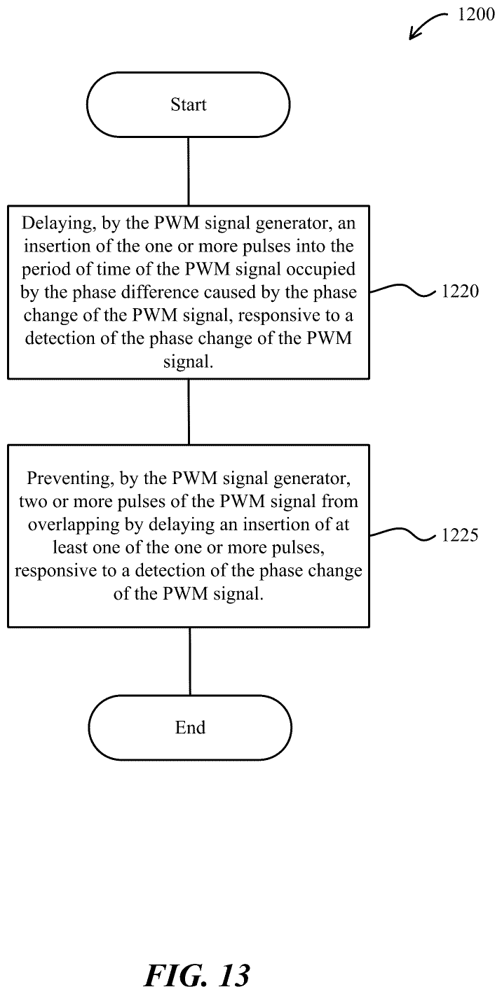

Referring now to FIG. 13, further optional blocks of method 1200 of FIG. 12 are shown, in accordance with an example aspect. Optional blocks of method 1200 shown in FIG. 13 relate to delaying the insertion of the one or more pulses into the period of time of the PWM signal due to the phase change corresponding to above-described flicker scenario 2 (decreasing phase from a higher value to a lower value).

At block 1220, the method 1200 includes delaying, by the PWM signal generator 210, an insertion of the one or more pulses into the period of time of the PWM signal occupied by the phase difference caused by the phase change of the PWM signal, responsive to a detection of the phase change. The signal is delayed to prevent pulse overlap. In an aspect, the pulse overlap may be between two or more pulses corresponding to two or more of a motor(s), a light(s), an audio amplifier(s), a telecommunications device(s), a power supply(s), a heating element(s), a buzzer(s), a sensor(s), a robotic(s), a computer motherboard(s), a solar panel(s), and so forth.

At block 1225, the method 1200 includes preventing, by the PWM signal generator 210, two or more pulses of the PWM signal from overlapping by delaying an insertion of at least one of the one or more pulses, responsive to a detection of the phase change of the PWM signal. In this way, two pulses that would otherwise overlap are made to be sequential to avoid both contributing to and possibly exceeding an expected average voltage/power.

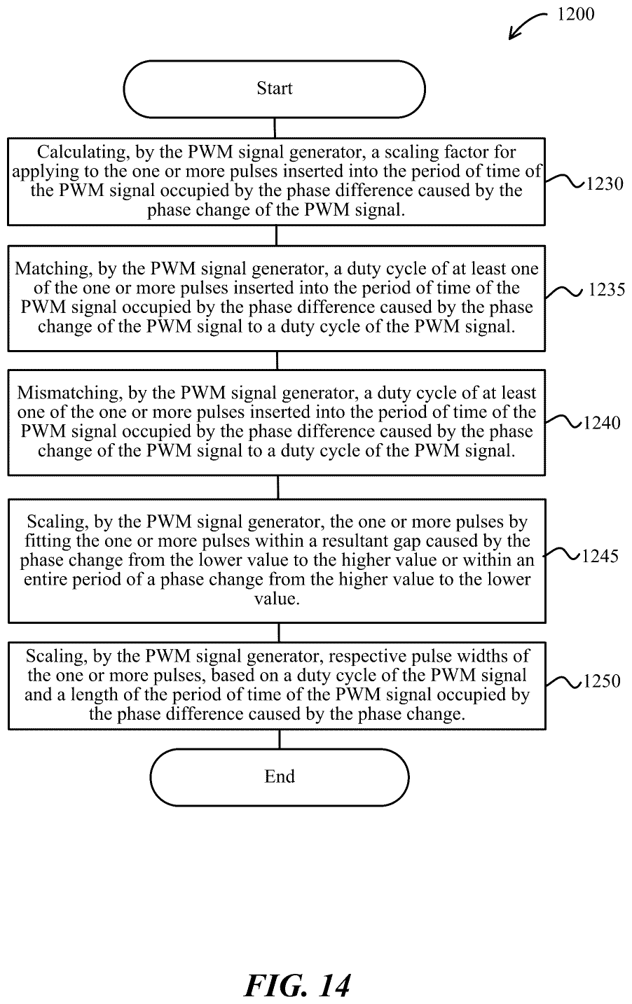

Referring now to FIG. 14, further optional blocks of method 1200 of FIG. 12 are shown, in accordance with an example aspect. Optional blocks of method 1200 shown in FIG. 14 relate to scaling the one or more pulses for insertion into the period of time of the PWM signal occupied by the phase difference caused by the phase change of the PWM signal.

At block 1230, the method 1200 includes calculating, by the PWM signal generator 210, a scaling factor for applying to the one or more pulses inserted into the period of time of the PWM signal occupied by the phase difference caused by the phase change of the PWM signal.

At block 1235, the method 1200 includes, in one optional aspect, matching, by the PWM signal generator 210, a duty cycle of at least one of the one or more pulses inserted into the period of time of the PWM signal occupied by the phase difference caused by the phase change of the PWM signal to a duty cycle of the PWM signal.

At block 1240, the method 1200 includes, in another optional aspect, mismatching, by the PWM signal generator 210, a duty cycle of at least one of the one or more pulses inserted into the period of time of the PWM signal occupied by the phase difference caused by the phase change of the PWM signal to a duty cycle of the PWM signal.

At block 1245, the method 1200 includes scaling, by the PWM signal generator 210, the one or more pulses by fitting the one or more pulses within a resultant gap caused by the phase change from the lower value to the higher value or within an entire period of a phase change from the higher value to the lower value.

At block 1250, the method 1200 includes scaling, by the PWM signal generator 210, respective pulse widths of the one or more pulses, based on a duty cycle of the PWM signal and a length of the period of time of the PWM signal occupied by the phase difference caused by the phase change. In an aspect, one or more pulses are generated such that the duty cycle of the one or more pulses matches the duty cycle of the PWM signal (being corrected). In an aspect, the one or more pulses are inserted into the period of time of the PWM signal occupied by the phase difference caused by the phase change with a matching duty cycle to the PWM signal being corrected, but with uniformly scaled pulse widths. That is, the scaled pulse widths are uniform in having a same width value. In an aspect, at least one pulse of the one or more pulses is inserted into the period of time of the PWM signal occupied by the phase difference caused by the phase change with a mismatched pulse width to another pulse of the one or more pulses.

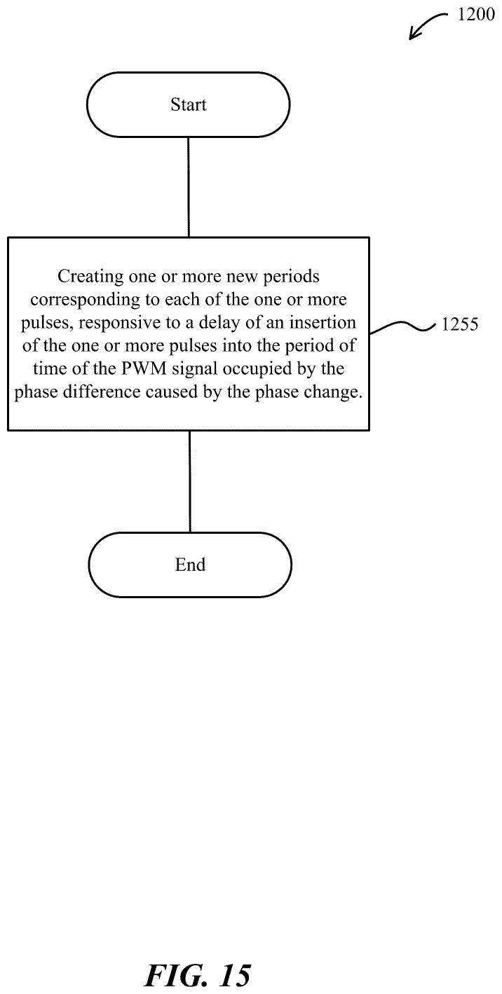

Referring now to FIG. 15, further optional blocks of method 1200 of FIG. 12 are shown, in accordance with an example aspect. Optional blocks of method 1200 shown in FIG. 15 relate to creating new signal periods in the PWM signal due to the phase change corresponding to above-described flicker scenario 2 (decreasing phase from a higher value to a lower value).

At block 1255, the method 1200 includes creating one or more new periods corresponding to each of the one or more pulses, responsive to a delay of an insertion of the one or more pulses into the period of time of the PWM signal occupied by the phase difference caused by the phase change. The insertion of the one or more pulses is delayed responsive to a detection of the phase change of the PWM signal. In an aspect, each of the one or more new periods is shorter than periods of other pulses of the PWM signal than the one or more pulses inserted in the period of time of the PWM signal occupied by the phase difference caused by the phase change.

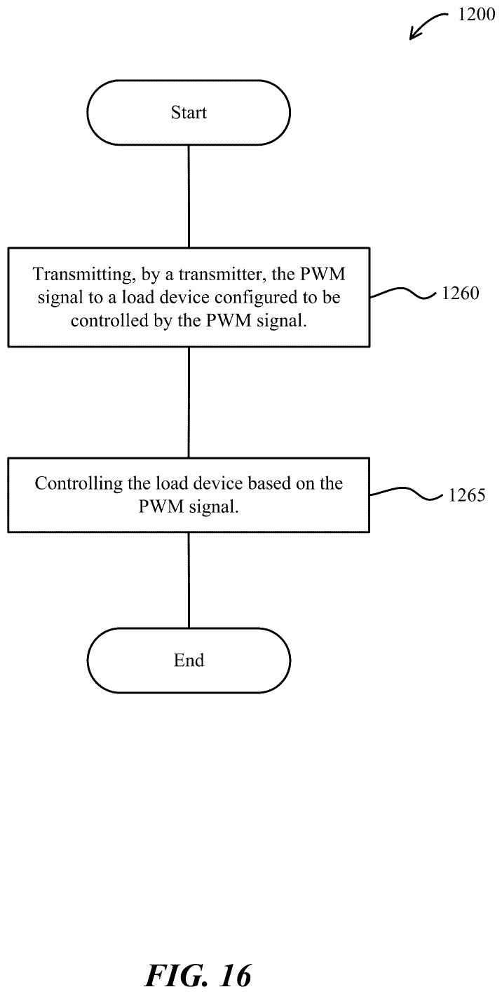

Referring now to FIG. 16, further optional blocks of method 1200 of FIG. 12 are shown, in accordance with an example aspect. Optional blocks of method 1200 shown in FIG. 16 relate to transmitting the PWM signal to a load device and controlling the operation of the load device.

At block 1260, the method 1200 includes transmitting, by a transceiver 215, the PWM signal to a load device 220 configured to be controlled by the PWM signal. In an aspect, the load device is any of a motor, a light, an audio amplifier, a telecommunications device, a power supply, a heating element, a buzzer, a sensor, a robotic, a computer motherboard, a solar panel, and so forth. In an aspect, the load device 120 is local to the PWM signal generator 210. In another aspect, the load device 120 is remote from the PWM signal generator 210.

At block 1265, the method 1200 includes controlling the load device 120 based on the PWM signal. For example, the PWM signal may speed up or slow down a motor, brighten or dim a light, reduce or increase an amplifier or power supply output, and so forth.

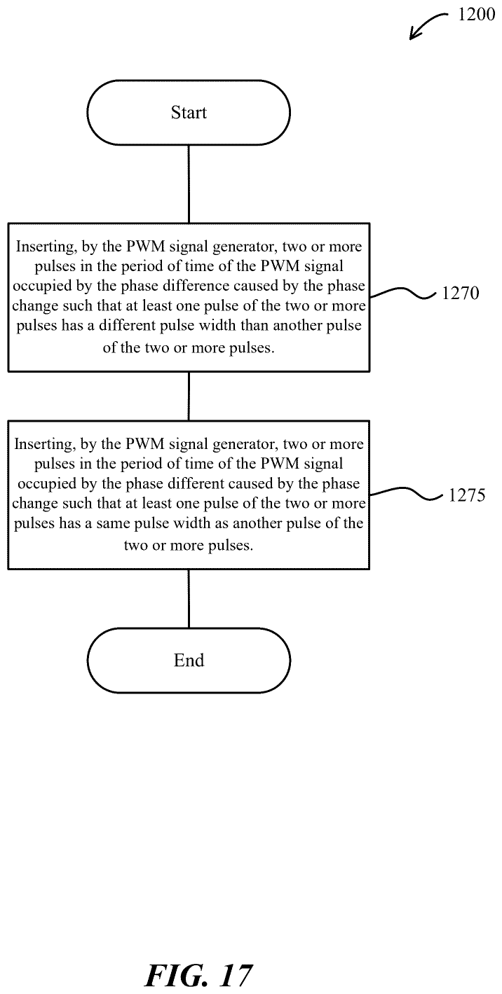

Referring now to FIG. 17, further optional blocks of method 1200 of FIG. 12 are shown, in accordance with an example aspect. Optional blocks of method 1200 shown in FIG. 17 relate to the pulse widths in the case of inserting two or more pulses.

At block 1270, the method 1200 includes, in an optional aspect, inserting, by the PWM signal generator 210, two or more pulses in the period of time of the PWM signal occupied by the phase difference caused by the phase change such that at least one pulse of the two or more pulses has a different pulse width than another pulse of the two or more pulses. In this way, non-unform pulses having different pulse widths can be used to raise the duty cycle in the period of time of the PWM signal occupied by the phase difference caused by the phase change

At block 1275, the method 1200 includes, in another optional aspect, inserting, by the PWM signal generator 210, two or more pulses in the period of time of the PWM signal occupied by the phase different caused by the phase change such that at least one pulse of the two or more pulses has a same pulse width as another pulse of the two or more pulses. In this way, unform pulses having identical pulse widths can be used to raise the duty cycle in the period of time of the PWM signal occupied by the phase difference caused by the phase change

Additional aspects of the present disclosure may include one or more of the following clauses.

Clause 1. A method for pulse width modulation (PWM), comprising: generating, by a PWM signal generator, a PWM signal; detecting, by the PWM signal generator, a phase change of the PWM signal from a lower value to a higher value or from the higher value to the lower value; and compensating, by the PWM signal generator, for a temporary decrease to a duty cycle of the PWM signal caused by the phase change by inserting one or more pulses into a period of time of the PWM signal occupied by a phase difference caused by the phase change of the PWM signal.

Clause 2. The method in accordance with clause 1, wherein an insertion of the one or more pulses into the PWM signal is performed by the PWM signal generator to cause a temporary increase to the duty cycle of the PWM signal that maintains at least one of an average voltage or an average power to a load device configured to receive the PWM signal.

Clause 3. The method in accordance with any preceding clauses, further comprising matching, by the PWM signal generator, a duty cycle of at least one of the one or more pulses inserted into the period of time of the PWM signal occupied by the phase difference caused by the phase change of the PWM signal to a duty cycle of the PWM signal.

Clause 4. The method in accordance with any preceding clauses, further comprising mismatching, by the PWM signal generator, a duty cycle of at least one of the one or more pulses inserted into the period of time of the PWM signal occupied by the phase difference caused by the phase change of the PWM signal to a duty cycle of the PWM signal.

Clause 5. The method in accordance with any preceding clauses, further comprising delaying, by the PWM signal generator, an insertion of the one or more pulses into the period of time of the PWM signal occupied by the phase difference caused by the phase change of the PWM signal, responsive to a detection of the phase change.

Clause 6. The method in accordance with any preceding clauses, further comprising calculating, by the PWM signal generator, a scaling factor for applying to the one or more pulses inserted into the period of time of the PWM signal occupied by the phase difference caused by the phase change of the PWM signal.

Clause 7. The method in accordance with any preceding clauses, further comprising scaling, by the PWM signal generator, the one or more pulses by fitting the one or more pulses within a resultant gap caused by the phase change from the lower value to the higher value or within an entire period of a phase change from the higher value to the lower value.

Clause 8. The method in accordance with any preceding clauses, further comprising scaling, by the PWM signal generator, respective pulse widths of the one or more pulses, based on a duty cycle of the PWM signal and a length of the period of time of the PWM signal occupied by the phase difference caused by the phase change.

Clause 9. The method in accordance with any preceding clauses, further comprising preventing, by the PWM signal generator, two or more pulses of the PWM signal from overlapping by delaying an insertion of at least one of the one or more pulses, responsive to a detection of the phase change of the PWM signal.

Clause 10. The method in accordance with any preceding clauses, further comprising creating, by the PWM signal generator, one or more new periods corresponding to each of the one or more pulses, responsive to a delay of an insertion of the one or more pulses into the period of time of the PWM signal occupied by the phase difference caused by the phase change, the insertion of the one or more pulses being delayed responsive to a detection of the phase change of the PWM signal.

Clause 11. The method in accordance with any preceding clauses, wherein each of the one or more new periods is shorter than periods of non-inserted pulses of the PWM signal.

Clause 12. The method in accordance with any preceding clauses, further comprising transmitting, by a transceiver, the PWM signal to a load device configured to be controlled by the PWM signal.

Clause 13. The method in accordance with any preceding clauses, wherein inserting one or more pulses comprises inserting two or more pulses in the period of time of the PWM signal occupied by the phase difference caused by the phase change such that at least one pulse of the two or more pulses has a different pulse width than another pulse of the two or more pulses.

Clause 14. The method in accordance with any preceding clauses, wherein inserting one or more pulses comprises inserting two or more pulses in the period of time of the PWM signal occupied by the phase difference caused by the phase change such that at least one pulse of the two or more pulses has a same pulse width as another pulse of the two or more pulses.

Clause 15. A system for pulse width modulation (PWM) signal, comprising: a PWM signal generator configured to: generate a PWM signal; detect a phase change of the PWM signal from a lower value to a higher value or from the higher value to the lower value; and compensate for a temporary decrease to a duty cycle of the PWM signal caused by the phase change by inserting one or more pulses into a period of time of the PWM signal occupied by a phase difference caused by the phase change of the PWM signal.

Clause 16. The system in accordance with clause 15, wherein the PWM signal generator is further configured to perform an insertion of the one or more pulses into the PWM signal generator to cause a temporary increase to the duty cycle of the PWM signal that maintains at least one of an average voltage or an average power to a load device configured to receive the PWM signal.

Clause 17. The system in accordance with any preceding clauses, wherein the PWM signal generator is further configured to match a duty cycle of at least one of the one or more pulses inserted into the period of time of the PWM signal occupied by the phase difference caused by the phase change of the PWM signal to a duty cycle of the PWM signal.

Clause 18. The system in accordance with any preceding clauses, wherein the PWM signal generator is further configured to mismatch a duty cycle of at least one of the one or more pulses inserted into the period of time of the PWM signal occupied by the phase difference caused by the phase change of the PWM signal to a duty cycle of the PWM signal.

Clause 19. The system in accordance with any preceding clauses, wherein the PWM signal generator is further configured to delay an insertion of the one or more pulses into the period of time of the PWM signal occupied by the phase difference caused by the phase change of the PWM signal, responsive to a detection of the phase change.

Clause 20. The system in accordance with any preceding clauses, wherein the PWM signal generator is further configured to calculate a scaling factor for applying to the one or more pulses inserted into the period of time of the PWM signal occupied by the phase difference caused by the phase change of the PWM signal.

Clause 21. The system in accordance with any preceding clauses, wherein the PWM signal generator is further configured to scale the one or more pulses by fitting the one or more pulses within a resultant gap caused by the phase change from the lower value to the higher value or within an entire period of a phase change from the higher value to the lower value.

Clause 22. The system in accordance with any preceding clauses, wherein the PWM signal generator is further configured to scale respective pulse widths of the one or more pulses, based on a duty cycle of the PWM signal and a length of the period of time of the PWM signal occupied by the phase difference caused by the phase change.

Clause 23. The system in accordance with any preceding clauses, wherein the PWM signal generator is further configured to prevent two or more pulses of the PWM signal from overlapping by delaying an insertion of at least one of the one or more pulses, responsive to a detection of the phase change of the PWM signal.

Clause 24. The system in accordance with any preceding clauses, wherein the PWM signal generator is further configured to create one or more new periods corresponding to each of the one or more pulses, responsive to a delay of an insertion of the one or more pulses into the period of time of the PWM signal occupied by the phase difference caused by the phase change, the insertion of the one or more pulses being delayed responsive to a detection of the phase change of the PWM signal.

Clause 25. The system in accordance with any preceding clauses, wherein each of the one or more new periods is shorter than periods of non-inserted pulses of the PWM signal.

Clause 26. The system in accordance with any preceding clauses, further comprising a transceiver configured to transmit the PWM signal to a load device configured to be controlled by the PWM signal.

Clause 27. The system in accordance with any preceding clauses, wherein the PWM signal generator is further configured to insert two or more pulses in the period of time of the PWM signal occupied by the phase difference caused by the phase change such that at least one pulse of the two or more pulses has a different pulse width than another pulse of the two or more pulses.

Clause 28. The system in accordance with any preceding clauses, wherein the PWM signal generator is further configured to insert two or more pulses in the period of time of the PWM signal occupied by the phase difference caused by the phase change such that at least one pulse of the two or more pulses has a same pulse width as another pulse of the two or more pulses.

Various aspects of the disclosure may take the form of an entirely or partially hardware aspect, an entirely or partially software aspect, or a combination of software and hardware. Furthermore, as described herein, various aspects of the disclosure (e.g., systems and methods) may take the form of a computer program product comprising a computer-readable non-transitory storage medium having computer-accessible instructions (e.g., computer-readable and/or computer-executable instructions) such as computer software, encoded or otherwise embodied in such storage medium. Those instructions can be read or otherwise accessed and executed by one or more processors to perform or permit the performance of the operations described herein. The instructions can be provided in any suitable form, such as source code, compiled code, interpreted code, executable code, static code, dynamic code, assembler code, combinations of the foregoing, and the like. Any suitable computer-readable non-transitory storage medium may be utilized to form the computer program product. For instance, the computer-readable medium may include any tangible non-transitory medium for storing information in a form readable or otherwise accessible by one or more computers or processor(s) functionally coupled thereto. Non-transitory storage media can include read-only memory (ROM); random access memory (RAM); magnetic disk storage media; optical storage media; flash memory, and so forth.

Aspects of this disclosure are described herein with reference to block diagrams and flowchart illustrations of methods, systems, apparatuses, and computer program products. It can be understood that each block of the block diagrams and flowchart illustrations, and combinations of blocks in the block diagrams and flowchart illustrations, respectively, can be implemented by computer-accessible instructions. In certain implementations, the computer-accessible instructions may be loaded or otherwise incorporated into a general-purpose computer, a special-purpose computer, or another programmable information processing apparatus to produce a particular machine, such that the operations or functions specified in the flowchart block or blocks can be implemented in response to execution at the computer or processing apparatus.

Unless otherwise expressly stated, it is in no way intended that any protocol, procedure, process, or method set forth herein be construed as requiring that its acts or steps be performed in a specific order. Accordingly, where a process or method claim does not actually recite an order to be followed by its acts or steps, or it is not otherwise specifically recited in the claims or descriptions of the subject disclosure that the steps are to be limited to a specific order, it is in no way intended that an order be inferred, in any respect. This holds for any possible non-express basis for interpretation, including: matters of logic with respect to the arrangement of steps or operational flow; plain meaning derived from grammatical organization or punctuation; the number or type of aspects described in the specification or annexed drawings; or the like.

As used in this disclosure, including the annexed drawings, the terms “component,” “module,” “system,” and the like are intended to refer to a computer-related entity or an entity related to an apparatus with one or more specific functionalities. The entity can be either hardware, a combination of hardware and software, software, or software in execution. One or more of such entities are also referred to as “functional elements.” As an example, a component can be a process running on a processor, a processor, an object, an executable, a thread of execution, a program, and/or a computer. For example, both an application running on a server or network controller, and the server or network controller can be a component. One or more components can reside within a process and/or thread of execution and a component can be localized on one computer and/or distributed between two or more computers. Also, these components can execute from various computer readable media having various data structures stored thereon. The components can communicate via local and/or remote processes such as in accordance with a signal having one or more data packets (e.g., data from one component interacting with another component in a local system, distributed system, and/or across a network such as the Internet with other systems via the signal). As another example, a component can be an apparatus with specific functionality provided by mechanical parts operated by electric or electronic circuitry, which parts can be controlled or otherwise operated by program code executed by a processor. As yet another example, a component can be an apparatus that provides specific functionality through electronic components without mechanical parts, the electronic components can include a processor to execute program code that provides, at least partially, the functionality of the electronic components. As still another example, interface(s) can include I/O components or Application Programming Interface (API) components. While the foregoing examples are directed to aspects of a component, the exemplified aspects or features also apply to a system, module, and similar.

In addition, the term “or” is intended to mean an inclusive “or” rather than an exclusive “or.” That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. Moreover, articles “a” and “an” as used in this specification and annexed drawings should be construed to mean “one or more” unless specified otherwise or clear from context to be directed to a singular form.

In addition, the terms “example” and “such as” and “e.g.” are utilized herein to mean serving as an instance or illustration. Any aspect or design described herein as an “example” or referred to in connection with a “such as” clause or “e.g.” is not necessarily to be construed as preferred or advantageous over other aspects or designs described herein. Rather, use of the terms “example” or “such as” or “e.g.” is intended to present concepts in a concrete fashion. The terms “first,” “second,” “third,” and so forth, as used in the claims and description, unless otherwise clear by context, is for clarity only and does not necessarily indicate or imply any order in time or space.

The term “processor,” as utilized in this disclosure, can refer to any computing processing unit or device comprising processing circuitry that can operate on data and/or signaling. A computing processing unit or device can include, for example, single-core processors; single-processors with software multithread execution capability; multi-core processors; multi-core processors with software multithread execution capability; multi-core processors with hardware multithread technology; parallel platforms; and parallel platforms with distributed shared memory. Additionally, a processor can include an integrated circuit, an application specific integrated circuit (ASIC), a digital signal processor (DSP), a field programmable gate array (FPGA), a programmable logic controller (PLC), a complex programmable logic device (CPLD), a discrete gate or transistor logic, discrete hardware components, or any combination thereof designed to perform the functions described herein.

In some cases, processors can exploit nano-scale architectures, such as molecular and quantum-dot based transistors, switches and gates, in order to optimize space usage or enhance performance of user equipment. A processor may also be implemented as a combination of computing processing units.

In addition, terms such as “store,” “data store,” data storage,” “database,” and substantially any other information storage component relevant to operation and functionality of a component, refer to “memory components,” or entities embodied in a “memory” or components comprising the memory. It will be appreciated that the memory components described herein can be either volatile memory or nonvolatile memory or can include both volatile and nonvolatile memory. Moreover, a memory component can be removable or affixed to a functional element (e.g., device, server).

Simply as an illustration, nonvolatile memory can include read only memory (ROM), programmable ROM (PROM), electrically programmable ROM (EPROM), electrically erasable ROM (EEPROM), or flash memory. Volatile memory can include random access memory (RAM), which acts as external cache memory. By way of illustration and not limitation, RAM is available in many forms such as synchronous RAM (SRAM), dynamic RAM (DRAM), synchronous DRAM (SDRAM), double data rate SDRAM (DDR SDRAM), enhanced SDRAM (ESDRAM), Synchlink DRAM (SLDRAM), and direct Rambus RAM (DRRAM). Additionally, the disclosed memory components of systems or methods herein are intended to comprise, without being limited to comprising, these and any other suitable types of memory.

The term “article of manufacture” as used herein is intended to encompass a computer program accessible from any non-transitory computer-readable device, carrier, or media. For example, computer readable media can include but are not limited to magnetic storage devices (e.g., hard drive disk, floppy disk, magnetic strips, or similar), optical discs (e.g., compact disc (CD), digital versatile disc (DVD), Blu-ray disc (BD), or similar), smart cards, and flash memory devices (e.g., card, stick, key drive, or similar).

The detail ended description set forth herein in connection with the annexed figures is intended as a description of various configurations or implementations and is not intended to represent the only configurations or implementations in which the concepts described herein may be practiced. The detail ended description includes specific detail ends for the purpose of providing a thorough understanding of various concepts. However, it will be apparent to those skilled in the art that these concepts may be practiced without these specific detail ends or with variations of these specific detail ends. In some instances, well-known components are shown in block diagram form, while some blocks may be representative of one or more well-known components.

The previous description of the disclosure is provided to enable a person skilled in the art to make or use the disclosure. Various modifications to the disclosure will be readily apparent to those skilled in the art, and the common principles defined herein may be applied to other variations without departing from the scope of the disclosure. Furthermore, although elements of the described aspects may be described or claimed in the singular, the plural is contemplated unless limitation to the singular is explicitly stated. Additionally, all or a portion of any aspect may be utilized with all or a portion of any other aspect, unless stated otherwise. Thus, the disclosure is not to be limited to the examples and designs described herein but is to be accorded the widest scope consistent with the principles and novel features disclosed herein.

What is claimed is:

1. A method for pulse width modulation (PWM), comprising:
generating, by a PWM signal generator, a PWM signal;
detecting, by the PWM signal generator, a phase change of the PWM signal from a lower value to a higher value or from the higher value to the lower value; and
compensating, by the PWM signal generator, for a temporary decrease to a duty cycle of the PWM signal caused by the phase change by inserting one or more pulses into a period of time of the PWM signal occupied by a phase difference caused by the phase change of the PWM signal.

2. The method in accordance with claim 1, wherein an insertion of the one or more pulses into the PWM signal is performed by the PWM signal generator to cause a temporary increase to the duty cycle of the PWM signal that maintains at least one of an average voltage or an average power to a load device configured to receive the PWM signal.

3. The method in accordance with claim 1, further comprising matching, by the PWM signal generator, a duty cycle of at least one of the one or more pulses inserted into the period of time of the PWM signal occupied by the phase difference caused by the phase change of the PWM signal to a duty cycle of the PWM signal.

4. The method in accordance with claim 1, further comprising mismatching, by the PWM signal generator, a duty cycle of at least one of the one or more pulses inserted into the period of time of the PWM signal occupied by the phase difference caused by the phase change of the PWM signal to a duty cycle of the PWM signal.

5. The method in accordance with claim 1, further comprising delaying, by the PWM signal generator, an insertion of the one or more pulses into the period of time of the PWM signal occupied by the phase difference caused by the phase change of the PWM signal, responsive to a detection of the phase change.

6. The method in accordance with claim 1, further comprising calculating, by the PWM signal generator, a scaling factor for applying to the one or more pulses inserted into the period of time of the PWM signal occupied by the phase difference caused by the phase change of the PWM signal.

7. The method in accordance with claim 1, further comprising scaling, by the PWM signal generator, the one or more pulses by fitting the one or more pulses within a resultant gap caused by the phase change from the lower value to the higher value or within an entire period of a phase change from the higher value to the lower value.

8. The method in accordance with claim 1, further comprising scaling, by the PWM signal generator, respective pulse widths of the one or more pulses, based on a duty cycle of the PWM signal and a length of the period of time of the PWM signal occupied by the phase difference caused by the phase change.

9. The method in accordance with claim 1, further comprising preventing, by the PWM signal generator, two or more pulses of the PWM signal from overlapping by delaying an insertion of at least one of the one or more pulses, responsive to a detection of the phase change of the PWM signal.

10. The method in accordance with claim 1, further comprising creating, by the PWM signal generator, one or more new periods corresponding to each of the one or more pulses, responsive to a delay of an insertion of the one or more pulses into the period of time of the PWM signal occupied by the phase difference caused by the phase change, the insertion of the one or more pulses being delayed responsive to a detection of the phase change of the PWM signal.

11. The method in accordance with claim 10, wherein each of the one or more new periods is less than or equal to a period of non-inserted pulses of the PWM signal.

12. The method in accordance with claim 1, further comprising transmitting, by a transceiver, the PWM signal to a load device configured to be controlled by the PWM signal.

13. The method in accordance with claim 1, wherein inserting one or more pulses comprises inserting two or more pulses in the period of time of the PWM signal occupied by the phase difference caused by the phase change such that at least one pulse of the two or more pulses has a different pulse width than another pulse of the two or more pulses.

14. The method in accordance with claim 1, wherein inserting one or more pulses comprises inserting two or more pulses in the period of time of the PWM signal occupied by the phase difference caused by the phase change such that at least one pulse of the two or more pulses has a same pulse width as another pulse of the two or more pulses.

15. A system for pulse width modulation (PWM) signal, comprising:
a PWM signal generator configured to:
generate a PWM signal;
detect a phase change of the PWM signal from a lower value to a higher value or from the higher value to the lower value; and
compensate for a temporary decrease to a duty cycle of the PWM signal caused by the phase change by inserting one or more pulses into a period of time of the PWM signal occupied by a phase difference caused by the phase change of the PWM signal.

16. The system in accordance with claim 15, wherein the PWM signal generator is further configured to perform an insertion of the one or more pulses into the PWM signal generator to cause a temporary increase to the duty cycle of the PWM signal that maintains at least one of an average voltage or an average power to a load device configured to receive the PWM signal.

17. The system in accordance with claim 15, wherein the PWM signal generator is further configured to match a duty cycle of at least one of the one or more pulses inserted into the period of time of the PWM signal occupied by the phase difference caused by the phase change of the PWM signal to a duty cycle of the PWM signal.

18. The system in accordance with claim 15 wherein the PWM signal generator is further configured to mismatch a duty cycle of at least one of the one or more pulses inserted into the period of time of the PWM signal occupied by the phase difference caused by the phase change of the PWM signal to a duty cycle of the PWM signal.

19. The system in accordance with claim 15, wherein the PWM signal generator is further configured to delay an insertion of the one or more pulses into the period of time of the PWM signal occupied by the phase difference caused by the phase change of the PWM signal, responsive to a detection of the phase change.

20. The system in accordance with claim 15, wherein the PWM signal generator is further configured to calculate a scaling factor for applying to the one or more pulses inserted into the period of time of the PWM signal occupied by the phase difference caused by the phase change of the PWM signal.

21. The system in accordance with claim 15, wherein the PWM signal generator is further configured to scale the one or more pulses by fitting the one or more pulses within a resultant gap caused by the phase change from the lower value to the higher value or within an entire period of a phase change from the higher value to the lower value.

22. The system in accordance with claim 15, wherein the PWM signal generator is further configured to scale respective pulse widths of the one or more pulses, based on a duty cycle of the PWM signal and a length of the period of time of the PWM signal occupied by the phase difference caused by the phase change.

23. The system in accordance with claim 15, wherein the PWM signal generator is further configured to prevent two or more pulses of the PWM signal from overlapping by delaying an insertion of at least one of the one or more pulses, responsive to a detection of the phase change of the PWM signal.

24. The system in accordance with claim 15, wherein the PWM signal generator is further configured to create one or more new periods corresponding to each of the one or more pulses, responsive to a delay of an insertion of the one or more pulses into the period of time of the PWM signal occupied by the phase difference caused by the phase change, the insertion of the one or more pulses being delayed responsive to a detection of the phase change of the PWM signal.

25. The system in accordance with claim 24, wherein each of the one or more new periods is less than or equal to a period of non-inserted pulses of the PWM signal.

26. The system in accordance with claim 15, further comprising a transceiver configured to transmit the PWM signal to a load device configured to be controlled by the PWM signal.

27. The system in accordance with claim 15, wherein the PWM signal generator is further configured to insert two or more pulses in the period of time of the PWM signal occupied by the phase difference caused by the phase change such that at least one pulse of the two or more pulses has a different pulse width than another pulse of the two or more pulses.

28. The system in accordance with claim 15, wherein the PWM signal generator is further configured to insert two or more pulses in the period of time of the PWM signal occupied by the phase difference caused by the phase change such that at least one pulse of the two or more pulses has a same pulse width as another pulse of the two or more pulses.
